(19) United States
(12) Patent Application Publication
(10) Pub. No.: US 2024/0128212 A1
(43) Pub. Date: Apr. 18, 2024

(54) SURFACE ENERGY MODIFICATION IN HYBRID BONDING

(71) Applicant: Tokyo Electron Limited, Tokyo (JP)

(72) Inventors: Joshua HOOGE, Austin, TX (US); Michael CARCASI, Austin, TX (US)

(73) Assignee: Tokyo Electron Limited, Tokyo (JP)

(21) Appl. No.: 18/313,177

(22) Filed: May 5, 2023

Related U.S. Application Data
(60) Provisional application No. 63/416,894, filed on Oct. 17, 2022.

(51) Int. Cl. H01L 23/00

(52) U.S. Cl. CPC H01L 24/05; H01L 24/03; H01L 24/80; H01L 2224/03452; H01L 2224/05578; H01L 2224/80895; H01L 2224/80896

(57) ABSTRACT

A semiconductor structure includes a semiconductor substrate and a dielectric layer disposed over the semiconductor substrate. The semiconductor structure includes a conductive feature embedded in the dielectric layer. The semiconductor structure includes a barrier layer disposed between the conductive feature and the dielectric layer. The semiconductor structure further includes a self-assembled monolayer (SAM) disposed over the barrier layer, at least a portion of the SAM directly contacting the conductive feature.

### CROSS-REFERENCE TO RELATED APPLICATIONS

The present application claims priority of U.S. Provisional Application No. 63/416,894, filed on Oct. 17, 2022, and titled “SURFACE ENERGY MODIFICATION IN HYBRID BONDING,” the entire disclosure of which is incorporated herein by reference for all purposes.

### FILED OF THE DISCLOSURE

This disclosure relates to methods of semiconductor manufacturing and more particularly to the bonding of multiple semiconductor substrates.

### BACKGROUND

Wafer-to-wafer, chip-to-chip, and chip to wafer bonding (generally, substrate bonding) is being implemented to continue Power-Performance-Area-Cost (PPAC) scaling for complex circuits such as are implemented in Systems on Chip (SOCs). Many bonding techniques, such as direct and hybrid bonding, utilize high pressure and/or temperature to achieve reliable oxide-to-oxide bonding adhesion between the substrates. For example, hybrid bonding forms a permanent bond that combines a dielectric bond with embedded metal to form interconnections. Lower temperature bonding technologies with excellent adhesion are desired.

FIGS. 1A, 1B, 1C, and 1D collectively illustrate some of the steps of a conventional process for bonding two semiconductor substrates (e.g., wafers) to form a semiconductor structure 100, though the process is abbreviated and simplified here as it is well known and merely for illustration purposes. A semiconductor substrate 101 includes a base substrate 102 and a plurality of active devices, metallization, and other circuitry features disposed within and/or over the base substrate 102. A dielectric layer 104 is formed over the base substrate 102. A barrier layer 105 is applied to reduce or eliminate any diffusion from conductive features 106 (e.g., conductive contacts). The conductive feature 106 may include copper (Cu). The conductive features 106 are formed at or below a bonding surface 108 of the dielectric layer 104. The bonding surface 108 is configured to engage and bond with another bonding surface 108 disposed over a different semiconductor substrate 101 to form the semiconductor structure 100. The dielectric layer 104 may include an oxide, a nitride, a carbide, the like, or combinations thereof, as is well known and described elsewhere. The conductive features 106 are often recessed to below the bonding surface 108 to ensure that, when two bonding surfaces are brought together, a strongly bonded dielectric-to-dielectric interface is formed prior to the conductive features 106 protruding and contacting each other across a bonding interface 110 therebetween. Referring to FIG. 1A, the bonding surface(s) 108 are activated using a plasma (e.g. such as an N₂ plasma and/or an O₂ plasma) to prepare the surfaces for bonding. Referring to FIG. 1B, hydration is often provided to further enhance the bonding capabilities of the bonding surface(s) 108. Referring to FIG. 1C, the bonding surfaces 108 of two semiconductor substrates 101 are aligned and brought into contact at the bonding interface 110. An anneal step, as shown in FIG. 1D, may improve the dielectric-to-dielectric bond and/or causes the conductive contacts to expand toward each other and create a physical and electrical contact as part of the semiconductor structure 100. One or both substrates may be thinned (not shown) as needed for a given application.

In practice, the conductive features 106 may make insufficient contact across the bonding interface 110 to adequately form an electrical connection with sufficiently low resistivity. Thus, procedures for improving contact formation in a hybrid bonding process are desired.

One conventional approach uses a technique to modulate the contact formation process. However, this process fails to optimize the surface energy between the contact and adjacent sidewalls.

### SUMMARY

Described herein are structures and techniques that provide for improved bonding (e.g., hybrid bonding) between substrates.

In one aspect, the present disclosure provides a semiconductor structure that includes a semiconductor substrate and a dielectric layer disposed over the semiconductor substrate. The semiconductor structure includes a conductive feature embedded in the dielectric layer. The semiconductor structure includes a barrier layer disposed between the conductive feature and the dielectric layer. The semiconductor structure further includes a self-assembled monolayer (SAM) disposed over the barrier layer, at least a portion of the SAM directly contacting the conductive feature.

In some implementations, the SAM is disposed between the conductive feature and the barrier layer such that an entirety of the SAM directly contacts the conductive feature. In some implementations, the SAM directly contacts a sidewall of the conductive feature and a sidewall of the barrier layer. In some implementations, a bottom surface of the conductive feature directly contacts the barrier layer.

In some implementations, the SAM directly contacts a top portion of a sidewall of the barrier layer, and the conductive feature directly contacts a bottom portion of the sidewall of the barrier layer below the top portion.

In some implementations, an interface between a top portion of the conductive feature and a top portion of the barrier layer has an inwardly sloped profile. In some implementations, an interface between a top portion of the barrier layer and a top portion of the dielectric layer has an outwardly sloped profile.

In another aspect, the present disclosure provides a semiconductor structure that includes a semiconductor substrate and a dielectric layer disposed over the semiconductor substrate, the dielectric layer having a recess. The semiconductor structure includes a conductive feature disposed in the recess. The semiconductor structure further includes a barrier layer disposed between the dielectric layer and the conductive feature. A top portion of a sidewall of the barrier layer has a sloped profile and a bottom portion of the sidewall of the barrier layer has a vertical profile.

In some implementations, the sloped profile is an inwardly sloped profile. In some implementations, the sloped profile is an outwardly sloped profile.

In some implementations, the semiconductor structure further includes a SAM disposed between the barrier layer and the conductive feature. In some implementations, the SAM directly contacts the top portion of the sidewall of the barrier layer, and wherein the conductive feature directly contacts a bottom portion of the sidewall of the barrier layer below the top portion.

In yet another aspect, the present disclosure provides a method that includes providing a semiconductor substrate and forming a bonding surface over the semiconductor substrate. Forming the bonding surface includes forming a dielectric layer over the semiconductor substrate. Forming the bonding surface includes forming a recess in the dielectric layer. Forming the bonding surface includes forming a barrier layer in the recess. Forming the bonding surface includes forming an SAM over the barrier layer. Forming the bonding surface further includes forming a conductive feature over the barrier layer, the conductive feature contacting at least a portion of the SAM.

In some implementations, the SAM is formed to directly contact sidewalls and a bottom surface of the barrier layer, such that the method further includes removing a portion of the SAM over the bottom surface of the barrier layer and subsequently forming the conductive feature over a remaining portion of the SAM. In some implementations, removing the portion of the SAM includes applying an anisotropic etching process using UV radiation with ozone. In some implementations, the method further includes recessing a top portion of the conductive feature to partially expose the SAM.

In some implementations, the conductive feature is formed to directly contact sidewalls and a bottom surface of the barrier layer, such that the method further includes removing a top portion of the conductive feature to partially expose the sidewalls of the barrier layer and subsequently forming the SAM over the recessed conductive feature and the partially exposed sidewalls of the barrier layer.

In some implementations, forming the barrier layer includes performing a deposition process being tuned to form the barrier layer having an outwardly sloped sidewall adjacent to a top surface of the dielectric layer. In some implementations, forming the barrier layer includes performing a deposition process being tuned to form the barrier layer having an inwardly sloped sidewall adjacent to a top surface of the dielectric layer.

In some implementations, the semiconductor substrate is a first semiconductor substrate, the bonding surface is a first bonding surface, and the conductive feature is a first conductive feature, such that the method further includes providing a second semiconductor substrate having a second bonding surface formed thereover, the second bonding surface including a second conductive feature. The method further includes bonding the first semiconductor substrate to the second semiconductor substrate to form a bonding interface. The method further includes annealing to fuse the first conductive feature with the second conductive feature across the bonding interface.

According to at least one embodiment, a self-assembled monolayer (SAM) is formed to contact a conductive feature (e.g., a Cu contact) at a bonding surface of a substrate. In some embodiments, the SAM is formed upon a barrier layer before forming the conductive feature in an opening of a dielectric layer, where exposed surfaces of the conductive feature and the dielectric layer form the bonding surface of the substrate. In some embodiments, an anisotropic etching process is performed to remove a bottom portion of the SAM such that the SAM remains on at least a portion of the sidewalls of the barrier layer within the opening. In some implementations, the conductive feature is formed over the barrier layer in the opening to contact (e.g., directly or physically contact) the barrier layer in the bottom of the opening and contact (e.g., directly or physically contact) the SAM on the sidewalls of the opening. In some implementations, the conductive feature contacts (e.g., directly or physically contact) the bottom surface and the sidewalls of the barrier layer and the SAM contacts (e.g., directly or physically contact) the sidewalls of the barrier layer over a top surface of the conductive feature. The SAM may effectively optimize the surface energy of the underlying layer over which the conductive feature is formed, thereby allowing more of a central portion of the conductive feature to expand during an annealing process as well as reducing or removing small voids formed at edges of the conductive feature as a result of such expansion, leading to increased physical and electrical contact between opposing conductive features. Accordingly, improved physical and electrical connections are achieved between the conductive features across a bonding interface in a bonded structure.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1A, 1B, 1C, and 1D collectively illustrate an example hybrid bonding process according to conventional techniques.

FIGS. 2, 3, 4, and 5 each illustrate a flowchart of an example method of fabricating a semiconductor structure, in accordance with some embodiments.

FIGS. 6A, 6B, 6C, 6D, 6E, and 6F each illustrate a cross-sectional side view of an example semiconductor structure at intermediate steps of the method illustrated in one or more of FIGS. 2, 3, 4, and 5, in accordance with some embodiments.

FIG. 7 illustrates an example structure of a portion of a self-assembled monolayer (SAM) adsorbed onto a portion of a semiconductor substrate, in accordance with some embodiments.

FIGS. 8A, 8B, 8C, and 8D each illustrate a cross-sectional side view of an example semiconductor structure at intermediate steps of the method illustrated in one or more of FIGS. 2, 3, 4, and 5, in accordance with some embodiments.

FIGS. 9, 10, 11, 12, 13, and 14 each illustrate a cross-sectional side view of an example semiconductor structure, in accordance with some embodiments.

FIGS. 15A, 15B, 15C, 15D, and 16 each illustrate a cross-sectional side view of an example semiconductor structure at intermediate steps of the method illustrated in one or more of FIGS. 2, 3, 4, and 5, in accordance with some embodiments.

FIGS. 17A, 17B, 17C, 17D, and 18 each illustrate a cross-sectional side view of an example semiconductor structure at intermediate steps of the method illustrated in one or more of FIGS. 2, 3, 4, and 5, in accordance with some embodiments.

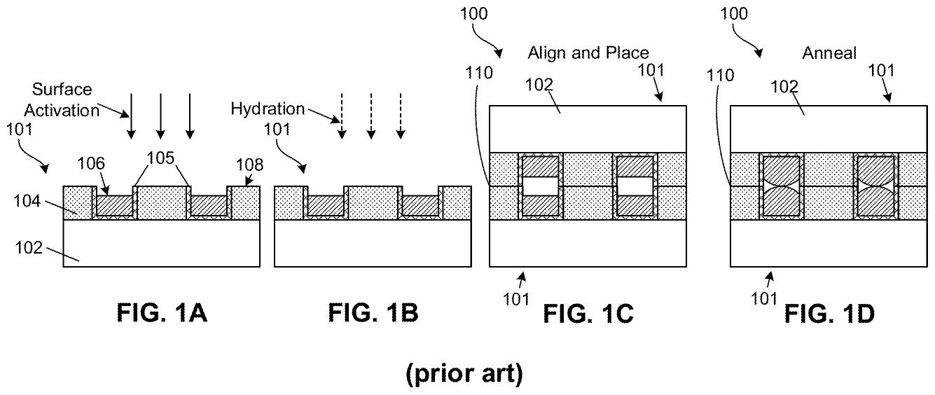

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used or other changes may be made without departing from the spirit or scope of the present disclosure. The illustrative embodiments described in the detailed description are not meant to be limiting of the subject matter presented.

According to one implementation, a first semiconductor structure (e.g., a first semiconductor substrate, a first semiconductor wafer, a first semiconductor die, etc.) is formed and processed before being bonded to a second semiconductor structure (e.g., a second semiconductor substrate, a second semiconductor wafer, a second semiconductor die, etc.), leading to an improved hybrid bonding technique in fabrication of semiconductor devices.

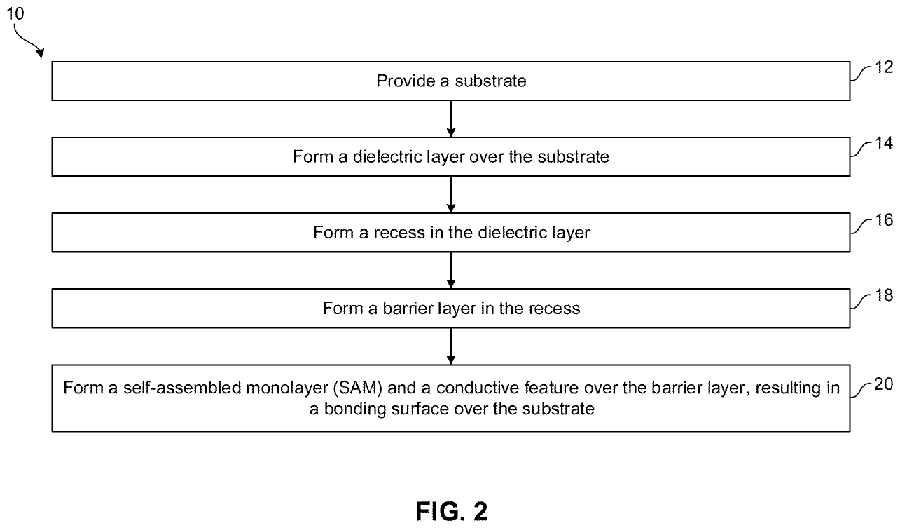

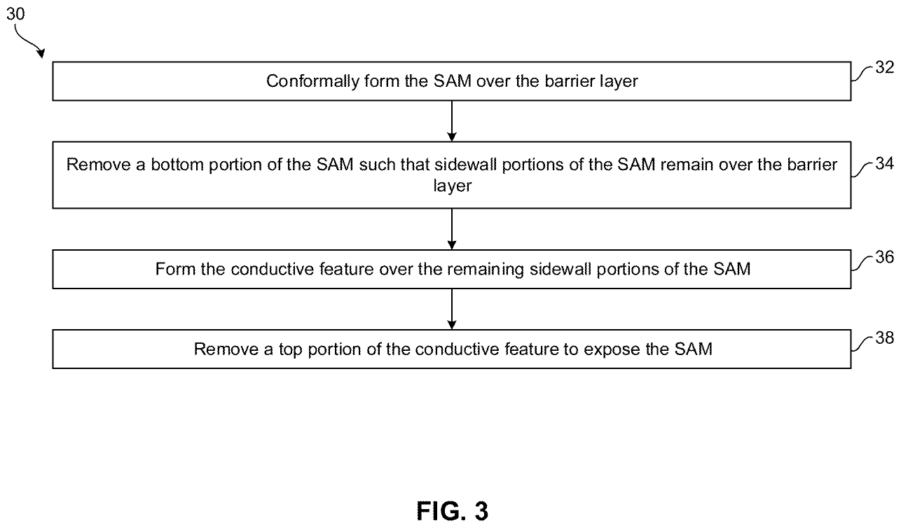

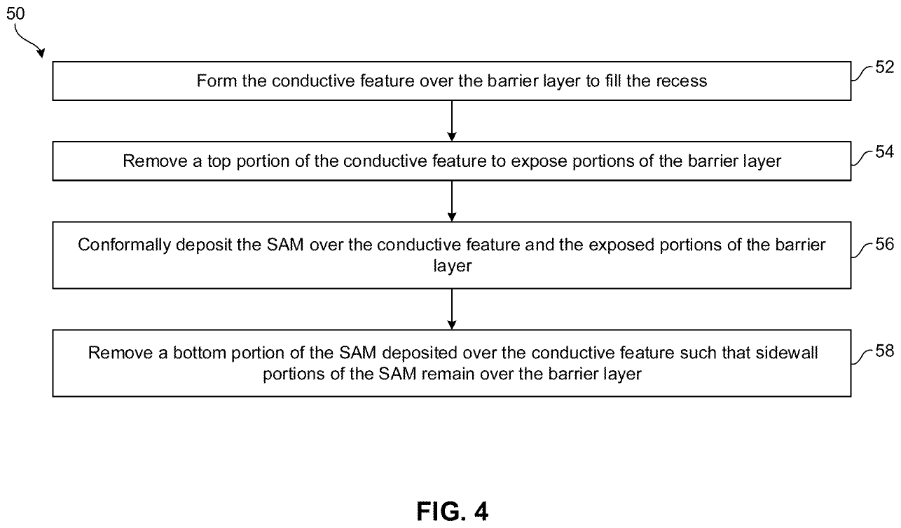

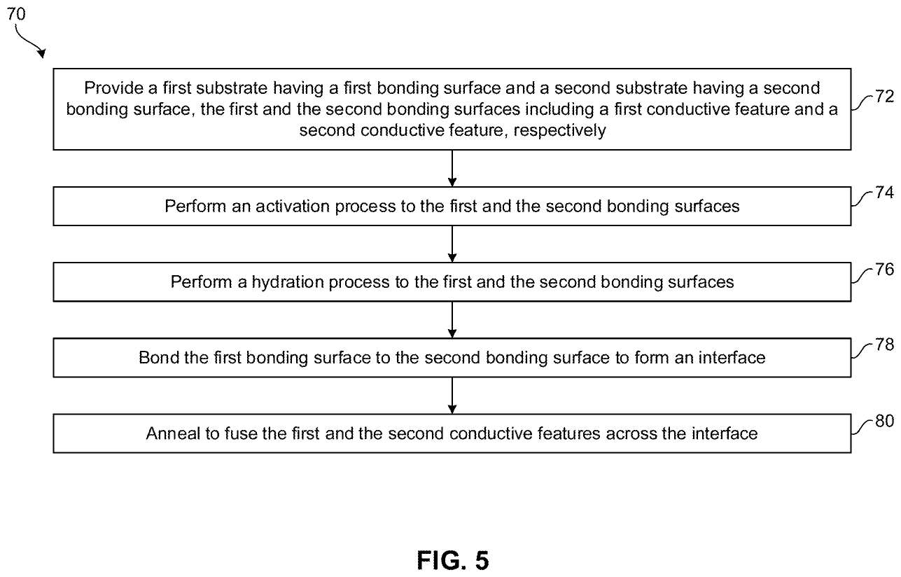

FIG. 2 illustrates a flowchart of an example method 10 for forming a bonding surface over a semiconductor structure, according to some implementations of the present disclosure. FIGS. 3 and 4 illustrate a flowchart of example methods 30 and 50, respectively, for implementing a portion (e.g., one or more operations) of the method 10, according to some implementations of the present disclosure. FIG. 5 illustrates a flowchart of an example method 70 for bonding or coupling bonding surfaces of two semiconductor structures (e.g., two semiconductor substrates, two semiconductor wafers, two semiconductor dies, etc.), according to some implementations of the present disclosure. It is noted that the methods 10, 30, 50, and 70 are merely examples and are not intended to limit the present disclosure. It is further understood that additional operations may be provided before, during, and after the method 10 of FIG. 2, the method 30 of FIG. 3, the method 50 of FIG. 4, and/or the method 70 of FIG. 5, and that some other operations may only be briefly described herein.

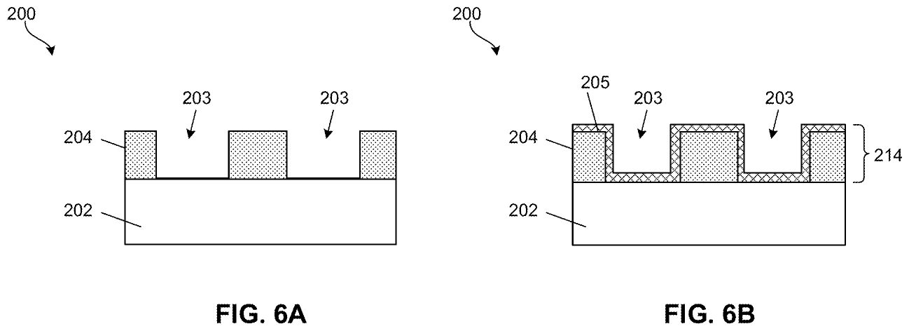

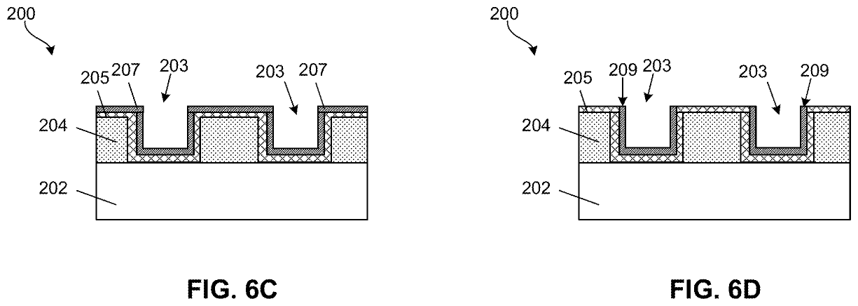

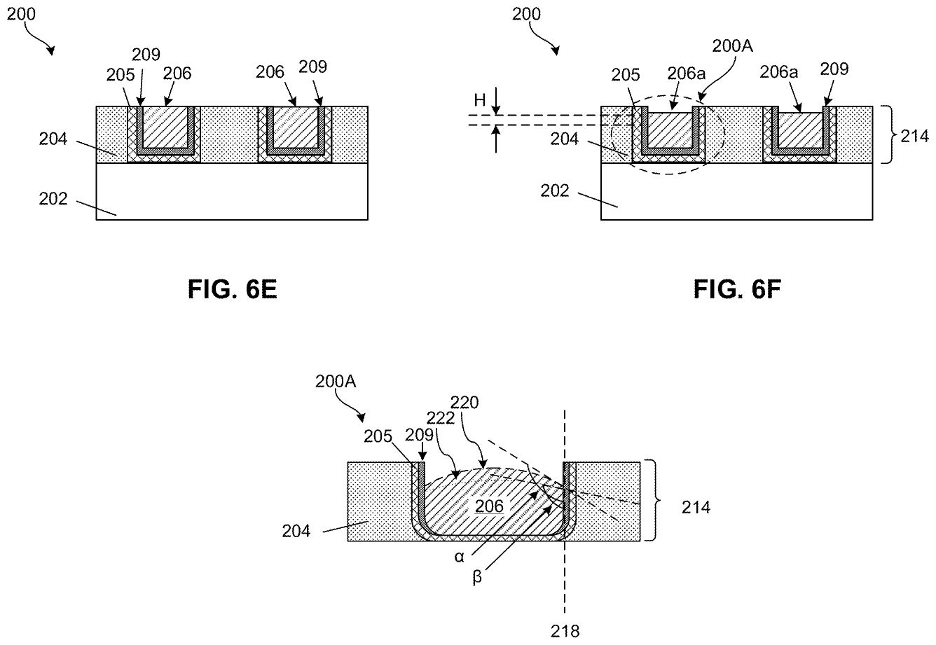

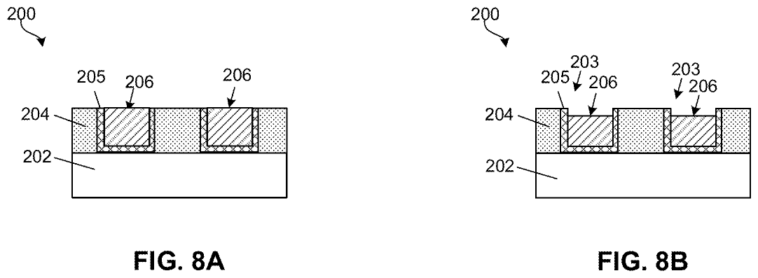

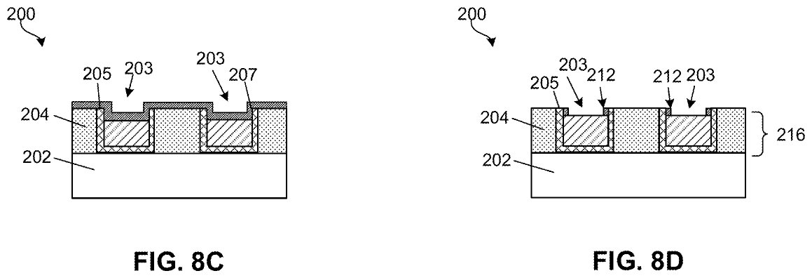

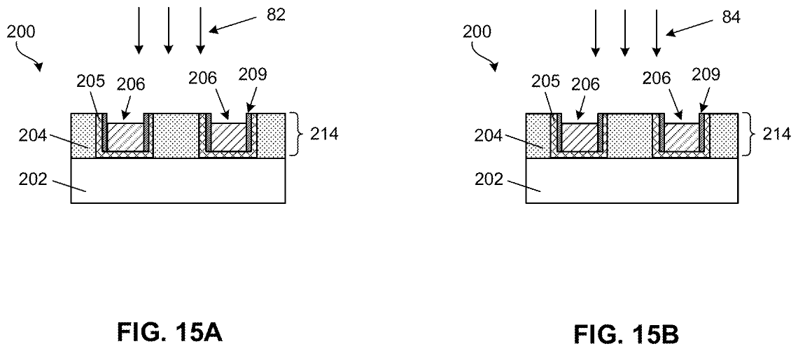

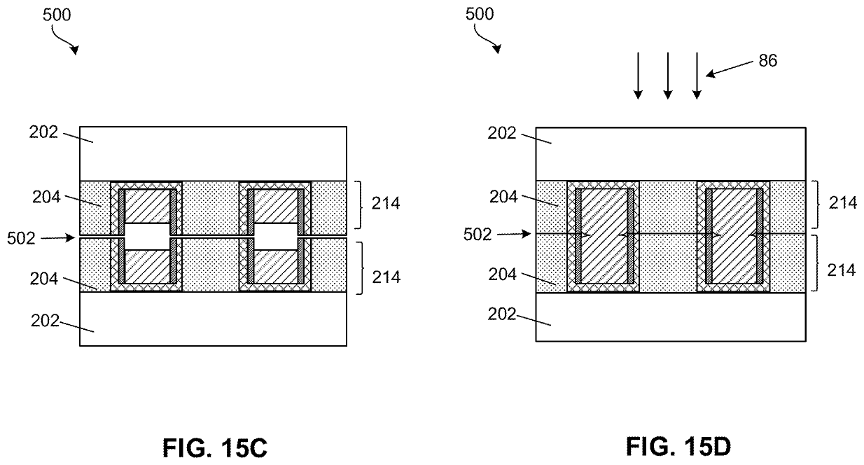

In various implementations, operations of the method 10 may be associated with an example semiconductor structure 200 at various fabrication stages, and operations of the method 70 may be associated with an example semiconductor structure 500 at various fabrication stages, which will be discussed in further detail below. It should be understood that the semiconductor structures 200 and 500 may each include a number of other devices such as inductors, fuses, capacitors, coils, etc., while remaining within the scope of the present disclosure. According to some implementations of the present disclosure, FIGS. 6A-6F illustrate cross-sectional side views of the semiconductor structure 200 at intermediate operations of the methods 10 and 30; FIGS. 8A-8D illustrate cross-sectional side views of the semiconductor structure 200 at intermediate operations of the methods 10 and 50; and FIGS. 15A-16 and 17A-18 illustrate cross-sectional side views of the semiconductor structure 500 at intermediate operations of the method 70.

Referring to FIGS. 2 and 6A, the method 10 at operation 12 provides the semiconductor structure 200 that includes a semiconductor substrate (e.g., a base substrate) 202.

The semiconductor substrate 202 includes a semiconductor material, such as a bulk semiconductor, a semiconductor-on-insulator (SOI), or the like, which may be doped (e.g., with a p-type or an n-type dopant) or undoped. The semiconductor substrate 202 may be or correspond to a wafer (e.g., 202 or 204), such as a silicon wafer. Generally, an SOI includes a layer of a semiconductor material formed on an insulator layer. The insulator layer may be, for example, a buried oxide (BOX) layer, a silicon oxide layer, or the like. The semiconductor substrate 202 may include other semiconductor materials, such as a multi-layered or gradient semiconductor material. In some examples, the semiconductor substrate 202 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Referring to FIGS. 2 and 6B, the method 10 at operation 14 forms a dielectric layer (e.g., insulating layer) 204 on or overlaying the semiconductor substrate 202. In the present implementations, the dielectric layer 204 and the subsequently-formed conductive features formed therein constitute a bonding surface 214 of the semiconductor structure 200. In some implementations, the bonding surface 214 is over a front side of the semiconductor substrate 202 (e.g., over a surface that includes the device features of the semiconductor structure 200). Alternatively, the bonding surface 214 may be over a back side of the semiconductor substrate 202 (e.g., over a surface opposing the device features of the semiconductor structure 200).

The dielectric layer 204 may include any suitable material, such as an oxide, a nitride, a carbide, the like, or combinations thereof. Non-limiting examples include silicon oxide (SiO₂), silicon nitride (SiN), silicon carbo-nitride (SiCN), a low-k dielectric material (e.g., a dielectric material having a dielectric constant less than that of silicon oxide, which is about 3.9), the like, or combinations thereof. The dielectric layer 204 may be formed or deposited using at least one suitable deposition technique, such as chemical vapor deposition (CVD), flowable CVD (FCVD), atomic layer deposition (ALD), spin coating, the like, or combinations thereof.

Though not depicted separately for the sake of simplicity, the semiconductor structure 200 may include a number of device features (e.g., transistors, diodes, resistors, etc.) within and/or over the semiconductor substrate 202 and a number of interconnect structures (alternatively referred to as conductive features, such as vias and conductive lines) formed over the device features. Example transistors may include field-effect transistors (FETs) such as fin-like FET (e.g., FinFET), multi-gate FETs, nanosheet FETs, the like, or combinations thereof. The interconnect structures may be configured to electrically connect the device features to one another so as to form an integrated circuit, which can function as a logic device, a memory device, an input/output device, or the like. The device features may include doped or undoped semiconductor materials, which may be similar in composition as the semiconductor substrate 202. The interconnect structures may include a conductive material, such as Cu, tungsten (W), nickle (Ni), aluminum (Al), ruthenium (Ru), silver (Ag), gold (Au), platinum (Pt), titanium (Ti), tantalum (Ta), TiN, TaN, the like, or combinations thereof, disposed in a dielectric (e.g., insulating) material, such as oxide, nitride, carbide, the like, or combinations thereof. The device features and the interconnect structures may be formed within intervening dielectric layers (e.g., intermetal dielectric layers, interlevel/interlayer dielectric layers, etch-stop layers, etc.) between the semiconductor substrate 202 and the dielectric layer 204, such as in a front-end-of-line (FEOL) or back-end-of-line (BEOL) layers. The intervening dielectric layers may be similar to the dielectric layer 204 in composition.

Still referring to FIGS. 2 and 6A, the method 10 at operation 16 forms a recess (e.g., a trench) 203 in the dielectric layer 204 to expose one or more underlying conductive features (e.g., metallization layers, interconnect structures, device features, etc.).

In some implementations, the recess 203 is formed by performing a patterning process. For example, a patterned mask layer (not depicted) may be formed over the dielectric layer 204 using a suitable lithography technique, where the patterned mask layer is formed with an opening corresponding to a position of the recess 203, and the dielectric layer 204 may be etched or patterned using the patterned mask layer as an etch mask, resulting in the recess 203 in the dielectric layer 204.

Referring to FIGS. 2 and 6B, the method 10 at operation 18 forms a barrier layer 205 over the dielectric layer 204.

The barrier layer 205 may include any suitable material, such as a TiN, TaN, Ti, Ta, Ru, the like, or combinations thereof. The barrier layer 205 is configured to reduce or prevent diffusion of metal atoms from the surrounding conductive features (e.g., the subsequently-formed conductive feature 206) into the dielectric layer 204. In some implementations, the barrier layer 205 is formed conformally over the dielectric layer 204, thereby lining a bottom and sidewall surfaces of the recess 203 and over a top surface of the dielectric layer 204. The barrier layer 205 may be deposited by any suitable deposition technique, such as CVD, ALD, physical vapor deposition (PVD), the like, or combinations thereof.

Subsequently, the method 10 at operation 20 forms a self-assembled monolayer (SAM) 207 and a conductive feature 206 over the barrier layer 205. As shown, referring to FIGS. 3 and 6C-6F collectively, operation 20 may be implemented by the method 30.

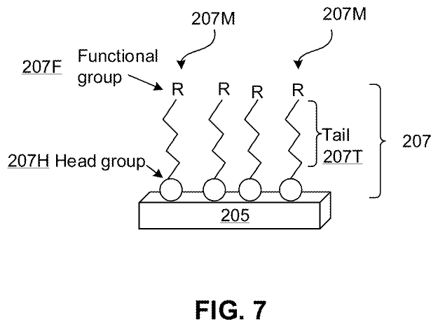

Referring to FIGS. 3 and 6C, the method 30 at operation 32 forms the SAM 207 over the barrier layer 205 within the recess 203 and over the top surface of the dielectric layer 204. In some implementations, the SAM 207 is a monolayer deposited conformally over the barrier layer 205 by a suitable method, such as spin coating, vapor deposition (e.g., CVD, ALD, etc.), or the like. Referring to FIG. 7, which illustrates a portion of the semiconductor structure 200, the SAM 207 includes a plurality of molecules 207M adsorbed or otherwise bonded to the underlying barrier layer 205 during a process driven by molecular interaction between portions of the molecules 207M and the surrounding features (e.g., the barrier layer 205).

As shown, each molecule 207M includes a head group 207H coupled to a first end of a tail (e.g., a spacer) 207T, which extends away from the head group 207H when assembled into the SAM 207. In some implementations, the head group 207H and the tail 207T are configured to have different polarities. The molecule 207M may further include at least one functional group 207F coupled to a second end of the tail 207T distal from the head group 207H. In the depicted implementations, the head groups 207H adsorb or otherwise bond to the barrier layer 205 with the tails 207T extending away from the barrier layer 205. The head groups 207H may bond to the barrier layer 205 via any suitable intermolecular interaction including, for example, ionic bonding, van der Waals bonding, covalent bonding, or the like. In some implementations, the function groups 207F participate in the subsequent bonding of the semiconductor structure 200 with another semiconductor structure to form a bonding interface discussed in detail below. In this regard, composition and/or structure of the head group 207H may be configured based on the composition of the barrier layer 205 to accommodate the adsorption or bonding between the SAM 207 and the barrier layer 205, while composition and/or structure of the functional group 207F may be configured to accommodate the formation of the bonding interface.

In some implementations, the head group 207H includes a generally polar moiety and the tail 207T includes a plurality of generally non-polar moieties coupled together. In some examples, the head group 207H may include a hydrophilic moiety (e.g., having general affinity toward polar surfaces) and the tail 207T may include a hydrophobic moiety (e.g., having general affinity toward non-polar surfaces). In some examples, the head group 207H may include moieties having one or more thiol groups (e.g., —SH). In some examples, the tail 207T may include an aliphatic or alkyl chain (e.g., a plurality of alkane moieties coupled together). In some examples, the functional group 207F may include one or more hydroxyl groups (e.g., —OH).

In some implementations, composition of the molecule 207M is tuned such that the barrier layer 205 may be omitted from the semiconductor structure 200. For example, silane-containing molecules 207M containing phosphorous in the head group 207H may form an SAM 207 capable of bonding to the underlying dielectric layer 204 in the recess 203 and providing thermal stability at a temperature up to about 300° C. to about 350° C. In this regard, the SAM 207 is formed to directly contact exposed surfaces (e.g., bottom and sidewall surfaces) of the recess 203 as well as the top surface of the dielectric layer 204. As used herein, the term “directly contact” or “in direct contact with” refers to surfaces in physical contact with one another without any intervening materials therebetween.

In some implementations, the surface energy of the SAM 207 can be tuned by adjusting the composition and/or structure of portions of the molecule 207M. In some implementations, the surface energy of the SAM 207 may be lowered by adjusting the composition and/or structure of the functional group 207F. For example, increasing the polarity (e.g., hydrophilicity) of the functional group 207F may increase the surface energy of the SAM 207, and vice versa. As will be discussed in detail below, the surface energy of the SAM 207 may be tuned to improve the formation of the conductive feature (e.g., the conductive feature 206) formed within the recess 203 during a subsequent bonding process.

Non-limiting examples of the molecule 207M may include napthalenthiols, 1H, 1H, 2H, 2H-perfluorodecyltriethoxysilanes, phosphonic acids, or the like. As one example, alkyl-containing molecules 207M with phosphonic acid incorporated in each head group 207H may bond to a TiN-containing surface (e.g., the barrier layer 205) and form molecular conjunctions including TiN/SAM/Ti. Additional and/or alternative SAM materials may also be applicable for the present implementations. These and other materials well known in the art have been shown to be thermally stable at temperatures suitable for processing the semiconductor structure 200 (e.g., about 300° C. to about 350° C.), although other temperatures ranges may also be achievable depending on specific composition and/or structure of the molecules 207M.

Referring back to FIGS. 3 and 6D, the method 30 at operation 34 removes portions of the SAM 207 formed on the bottom surface of the recess 203 and on the top surface of the barrier layer 205 from the semiconductor structure 200, thereby exposing the underlying barrier layer 205.

In the present implementations, portions of the SAM 207 extending generally parallel to the top surface of the semiconductor substrate 202 are anisotropically removed by a selective (e.g., directional) etching process, leaving portions of the SAM 207 extending generally perpendicular to the top surface of the semiconductor substrate 202 substantially intact. In this regard, the remaining portions of the SAM 207 form spacers 209 along the sidewall surfaces of the barrier layer 205 within the recess 203. In some implementations, the selective etching process is implemented using UV radiation with ozone. Other anisotropic processes, such as plasma-assisted etching, may additionally or alternatively be used to form the spacers 209. In some implementations, operation 34 may be omitted.

Referring to FIGS. 3 and 6E, the method 30 at operation 36 forms the conductive feature (e.g., conductive contact) 206 over the spacers 209, thereby filling the recess 203.

The conductive feature 206 may include any suitable conductive material including Cu, W, Ni, Al, ru, Ag, Au, Pt, Ti, Ta, TiN, TaN, the like, or combinations thereof. In the depicted implementations, the conductive feature 206 includes Cu. In some implementations, a conductive layer may be deposited as a blanket layer over the semiconductor structure 200 to fill the recess 203 and overlay the top surface of the dielectric layer 204. The conductive layer may be deposited by any suitable deposition technique, such as CVD, ALD, PVD, plating (e.g., electroplating, electroless plating, etc.), the like, or combinations thereof. The blanket layer and any underlying layers (e.g., the SAM 207 and/or the barrier layer 205) may then be etched (e.g., by a dry etching, a reactive ion etching (RIE), or a wet etching process) or polished (e.g., by a chemical-mechanical polishing/planarization, or CMP, process) until the surface of the dielectric layer 204 is exposed, thereby forming the conductive feature 206 in the dielectric layer 204. The conductive feature 206 may be formed as part of a middle-end-of-line (MEOL) process or a back-end-of-line (BEOL) process. For example, the conductive feature 206 may be formed as a bonding pad for coupling the semiconductor structure 200 to another semiconductor structure, die, substrate, or the like, as a portion of a package.

Referring to FIGS. 3 and 6F, the method 30 at operation 38 removes a top portion of the conductive feature 206 to expose portions of the spacer 209 in a top portion of the recess 203. As an example, the amount of the conductive feature 206 removed at operation 38 may be measured by a height H that is less than about 5 nm, such as about 1.5 nm, 2 nm, 3.7 nm, 4 nm, or the like. The conductive feature 206 may be etched by any suitable process, such as a dry etching process, a reactive ion etching (RIE) process, or a wet etching process. In some examples, the height H may be controlled by factors such as etching duration, etching power, and/or other factors.

In some implementations, removing the amount of the conductive feature 206 accommodates expansion of the conductive feature 206 on two opposing bonding surfaces 214 during the subsequent bonding process, thereby allowing sufficient physical contact between the dielectric layers 204 of the bonding surfaces 214. As will be discussed in detail below, such expansion may be influenced by one or more factors including interfacial properties (e.g., surface energy) of the underlying layer with respect to the conductive feature 206, thermal stress arising from heating, and/or mechanical strain energy incurred by the physical shape or profile of the underlying layer.

Referring to an enlarged depiction of portion 200A of the semiconductor structure 200, a top surface of the conductive feature 206 curves outward and projects away (e.g., having a convex surface) from the semiconductor substrate 202 along a curve 220. The curve 220 may be defined by a contact angle α relative to a reference axis 218 that extends vertically along the sidewall of the barrier layer 205 and is substantially perpendicular to the semiconductor substrate 202. In the present implementations, the degree of the “bulging out” of the curve 220, measured by the magnitude of the contact angle α, is determined based on the surface energy of the spacers 209 (or the SAM 207). In this regard, a lower surface energy of the spacer 209 leads to a greater degree of the bulging out and a larger contact angle α. In the present implementations, the contact angle α is generally an obtuse angle that is greater than about 90° and less than about 180°. For comparison purposes, a contact angle of about 90° equates to the top surface of the conductive feature 206 being substantially parallel to the semiconductor substrate 202 and perpendicular to the reference axis 218.

In the present implementations, the interfacial properties (e.g., the surface energy) of the barrier layer 205 is modified by the molecules 207M of the SAM 207 (or the spacers 209), such that the contact angle α of the conductive feature 206 is determined based on the surface property of the SAM 207. As provided herein, the surface energy of the molecules 207M may be tuned by adjusting the composition and/or structure of the functional group 207F coupled to the second end of the tail 207T distal to the head group 207H. In some implementations, decreasing the surface energy (i.e., increasing the contact angle α) of the SAM 207 may be achieved by reducing the polarity of the functional group 207F. For example, reducing the number of —OH groups incorporated in the functional group 207F causes the functional group 207F to be less polar or less hydrophilic, thereby reducing the surface energy of the SAM 207 and leading to a larger contact angle α. As will be discussed in detail below, additional or alternative modifications of other aspects of the semiconductor structure 200 may also lead to modifications of the profile of the conductive feature 206.

Accordingly, by adjusting the surface energy of the barrier layer 205 using the SAM 207 (i.e., the spacers 209), the contact angle α of the conductive feature 206 may be modified, leading to modification of the profile of the top surface of the conductive feature 206. For example, lowering the surface energy of the SAM 207 leads to a greater contact angle α and more bulging at the central portion of the top surface of the conductive feature 206, which allows the conductive features 206 of two opposing bonding surfaces 214 to expand toward each other to a greater extent and establish better contact (e.g., greater area of contact) across the bonding interface at a lower temperature (e.g., without undergoing thermal expansion) and/or absent applying any strain energy (discussed in detail below). In some instances, the surface energy of the barrier layer 205 may be optimized to reduce or remove small voids formed at edges of the conductive feature 206 as a result of such expansion, which may also lead to improved physical and electrical contact across the bonding interface. This may provide at least the benefit of improved thermal budget during fabrication process and greater design freedom to utilize various integration schemes. In contrast, curve 222, which represents the profile of the top surface of the conductive feature 206 without the spacers 209 lining the sidewall surfaces of the barrier layer 205, is depicted to have a lesser degree of bulging out and thus a lower contact angle β with respect to the reference axis 218.

In some implementations, the lowered surface energy provided by the spacers 209 allows a central region of the conductive feature 206 to expand more freely, amplifying the bulging effect. In some implementations, the expansion of the conductive feature 206 is driven by diffusion of atoms along the top surface of the conductive feature 206 due to changes in interfacial properties (e.g., surface energy), thermal stress, and/or mechanical stress of the underlying layer. By incorporating the SAM 207 with a lower surface energy, a larger surface energy gradient may be established between the conductive feature 206 and the SAM 207 (e.g., the SAM 207 along the sidewall surfaces of the recess 203), which results in a greater extent of the diffusion of the atoms across the top surface of the conductive feature 206. Such surface phenomenon may be described by increased contact angle α, increased curvature of the curve 220, and the bulging out of the conductive feature 206.

In alternative implementations, referring to FIGS. 4 and 8A-8D collectively, operation 20 of the method 10 may be implemented by the method 50 to form a bonding surface 216, which is similar, though not identical, to the bonding surface 214.

Referring to FIGS. 4 and 8A, the method 50 at operation 52 forms the conductive feature 206 over the barrier layer 205 to fill the recess 203. In some implementations, the process of forming the conductive feature 206 is similar to that of operation 36 described in detail above and therefore not repeated for purposes of brevity.

Referring to FIGS. 4 and 8B, the method 50 at operation 54 removes a top portion of the conductive feature 206 to expose sidewalls of the barrier layer 205 near the opening of the recess 203. In some implementations, the process of recessing the conductive feature 206 is similar to that of operation 38 described in detail above and therefore not repeated for purposes of brevity.

Referring to FIGS. 4 and 8C, the method 50 at operation 56 deposits the SAM 207 over a top surface of the recessed conductive feature 206 and the exposed sidewalls of the barrier layer 205. In some implementations, the process of depositing the SAM 207 is similar to that of operation 32 described in detail above and therefore not repeated for purposes of brevity. As shown, the bottom portion of the SAM 207 is formed to directly contact the top surface of the recessed conductive feature 206, rather than the bottom surface of the barrier layer 205 in the recess 203, as is the case for operation 32 depicted in FIG. 6C.

Subsequently, referring to FIGS. 4 and 8D, the method 50 at operation 58 removes the bottom portion of the SAM 207 to expose the top surface of the conductive feature 206, thereby forming the bonding surface 216. In some implementations, the process of removing the bottom portion of the SAM 207 (e.g., an anisotropic etching process) is similar to that of operation 34 described in detail above and therefore not repeated for purposes of brevity.

After removing the bottom portion of the SAM 207, portions of the SAM 207 remain as spacers 212 over the sidewalls of the barrier layer 205 and vertically above the conductive feature 206. In this regard, the spacers 212 are formed only near the opening of the recess 203 and therefore vertically extend a shorter distance than the spacers 209, which are each formed along an entire sidewall of the barrier layer 205.

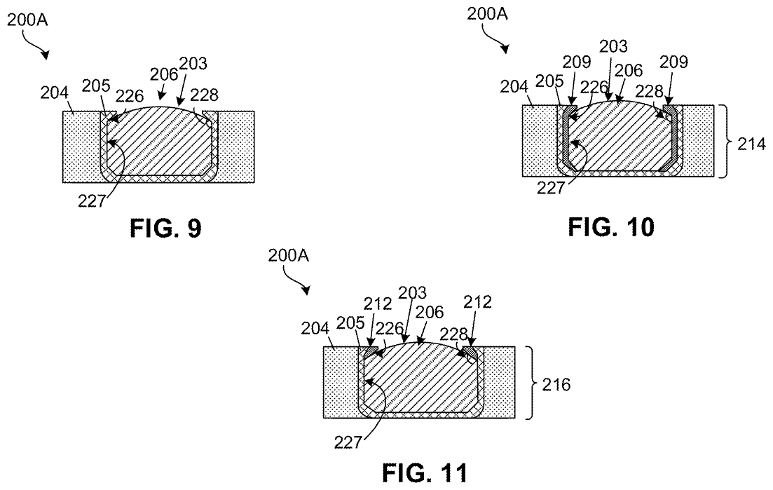

FIGS. 9-14 illustrate various embodiments of the portion 200A of the semiconductor structure 200 that may be additionally or alternatively implemented in which the profile of the recess 203, the barrier layer 205, and/or the SAM 207, whichever may be applicable, as a portion of or disposed adjacent the bonding surface (e.g., the bonding surface 214) is modified to improve the expansion process of the conductive feature 206 across a bonding interface shared with another conductive feature 206 during the bonding process.

Referring to FIGS. 9-11 collectively, the barrier layer 205 may be formed to have an inward slope (e.g., slanting inwardly toward the conductive feature 206) in upper inner sidewalls 226 adjacent the bonding surface. The inward slant of the upper inner sidewalls 226 narrows the opening of the recess 203 adjacent the top surface of the dielectric layer 204. Such inward slope (or inward slant) presents a retrograde surface in the upper inner sidewalls 226 defined by an angle 228 with respect to a substantially vertical lower inner sidewall 227 of the barrier layer 205. In this regard, the angle 228 is generally an obtuse angle, which is greater than 90° and less than 180°.

The upper inner sidewalls 226 generally exert stress from edges of the conductive feature 206 toward its center, thereby creating strain energy along the top surface of the conductive feature 206. In instances in which such strain energy is a primary driving force for the diffusion of the atoms along the top surface of the conductive feature 206 during the expansion process, the inwardly slanted upper inner sidewalls 226 cause the conductive feature 206 to bulge out more vertically, further enhancing the expansion of the conductive feature 206 during the bonding process. In the present implementations, the angle 228 can be tuned to create more or less of the projection of the top surface of the conductive feature 206.

In some implementations, referring to FIGS. 10 and 11, the upper inner sidewalls 226 may be combined with the SAM 207, which modifies the contact angle (e.g., the contact angle α defined herein) of the conductive feature 206 by tuning its surface energy, to further enhance the expansion of the conductive feature 206. For example, FIG. 10 corresponds to the implementation depicted in FIG. 6F, where the portion 200A includes the spacers 209 disposed along the sidewalls of the barrier layer 205 in the bonding surface 214, and FIG. 11 corresponds to the implementation depicted in FIG. 8D, where the portion 200A includes the spacers 212 disposed over the sidewalls of the barrier layer 205 and vertically above the conductive feature 206 in the bonding surface 216.

In some implementations, the strain energy contributed by the upper inner sidewalls 226 can enhance the expansion of the conductive feature 206 without needing the SAM 207, as depicted in FIG. 9. In some implementations, though not depicted, the sidewalls of the recess 203 may be additionally or alternatively modified to form an inward slope similar to that of the upper inner sidewalls 226.

In some examples, the upper inner sidewalls 226 may be formed during the deposition process implemented for forming the barrier layer 205, e.g., at operation 18 of the method 10. Alternatively or additionally, the upper inner sidewalls 226 may be formed during the formation of the recess 203 in the dielectric layer 204, e.g., at operation 16 of the method 10, by altering parameters of the etching process (e.g., changing direction of plasma source during a dry etching or an RIE process).

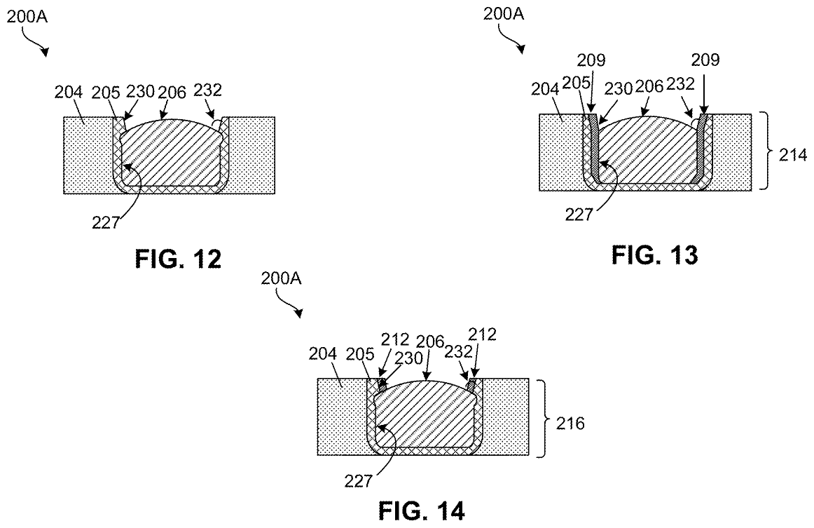

Referring to FIGS. 12-14 collectively, the barrier layer 205 may be formed to have an outward slope (e.g., projecting outwardly from the conductive feature 206) in upper inner sidewalls 230 adjacent the bonding surface (e.g., the bonding surface 216). The outward projection of the upper inner sidewalls 230 widens the opening of the recess 203 adjacent the bonding surface. Such outward slope (or outward slant) presents a surface in the upper inner sidewalls 230 defined by an angle 232 with respect to the lower inner sidewall 227 of the barrier layer 205. In this regard, the angle 228 is generally an acute angle, which is less than 90°.

In some implementations, the outward projection of the upper inner surface 230 can modify the contact angle (e.g., the contact angle α defined herein) of the conductive feature 206 to produce a more pronounced curvature (e.g., the curve 220 defined herein) in its top surface with respect to the reference axis 218, thereby creating an advantageously lower surface energy state in the bulged-out (central) portion as compared to the portions in contact with the sidewalls of the barrier layer 205. In the present implementations, the angle 232 can be tuned to create more or less of the projection of the top surface of the conductive feature 206.

In some implementations, referring to FIGS. 13 and 14, the upper inner sidewalls 230 may be combined with the SAM 207, which modifies the contact angle (e.g., the contact angle α defined herein) of the conductive feature 206 by tuning its surface energy, to further enhance the expansion of the conductive feature 206. For example, FIG. 13 corresponds to the implementation depicted in FIG. 6F, where the portion 200A includes the spacers 209 disposed along the sidewalls of the barrier layer 205 in the bonding surface 214, and FIG. 14 corresponds to the implementation depicted in FIG. 8D, where the portion 200A includes the spacers 212 disposed over the sidewalls of the barrier layer 205 and vertically above the conductive feature 206 in the bonding surface 216.

In some implementations, the lowered surface energy state contributed by the upper inner sidewalls 230 can enhance the expansion of the conductive feature 206 without needing the SAM 207, as depicted in FIG. 12. In some implementations, though not depicted, the sidewalls of the recess 203 may be additionally or alternatively modified to form an outward slope similar to that of the upper inner sidewalls 230.

In some examples, the upper inner sidewalls 230 may be formed during the deposition process implemented for forming the barrier layer 205, e.g., at operation 18 of the method 10. Alternatively or additionally, the upper inner sidewalls 230 may be formed during the formation of the recess 203 in the dielectric layer 204, e.g., at operation 16 of the method 10, by altering parameters of the etching process (e.g., changing direction of plasma source during a dry etching or an RIE process).

Accordingly, the shape and/or angle of the sidewalls of the barrier layer 205 may be tuned for a given application as the bulging or expansion effect may be dominated by strain energy (as shown in FIGS. 9-11) or contact angle (as shown in FIGS. 12-14). Thus, for example, in a case where strain energy is the dominating factor, tuning the sidewalls of the barrier layer 205 to include the inwardly sloping upper inner sidewalls 226 may accentuate the bulging effect, thereby enhancing the expansion of the conductive feature 206. In contrast, in a case where contact angle is the dominating factor, tuning the sidewalls of the barrier layer 205 to include the outwardly sloping upper inner sidewalls 230 may accentuate the bulging effect.

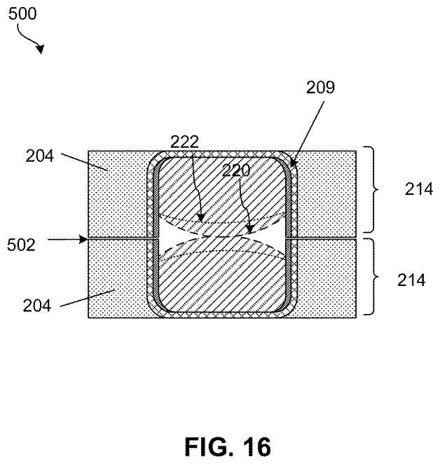

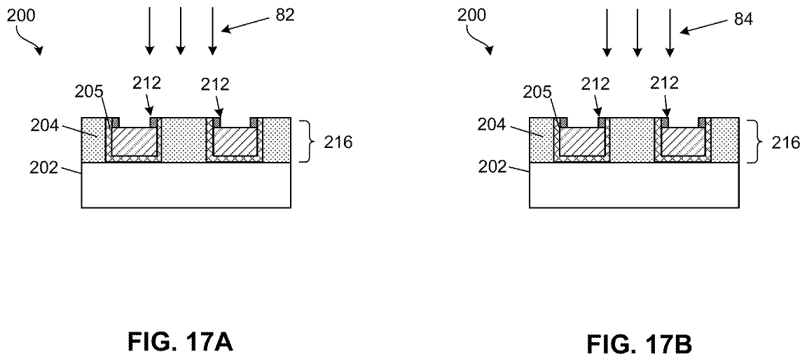

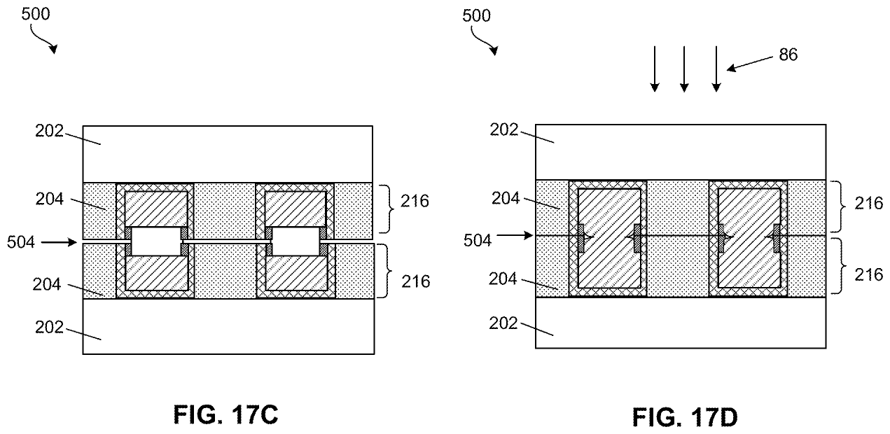

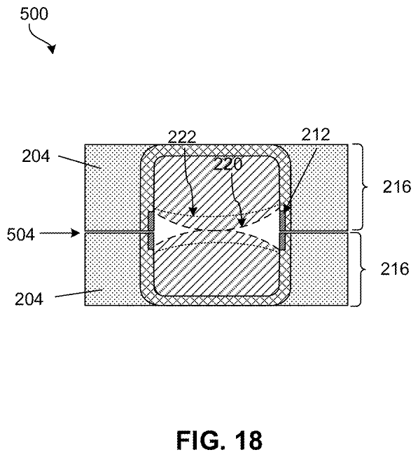

Now referring to FIGS. 5 and 15A-18, the method 70 provides an example process for bonding or coupling a bonding surface of one semiconductor structure with a bonding surface of another semiconductor structure. In the depicted implementations, FIGS. 15A-16 correspond to an example of the method 70 applied to coupling two bonding surfaces 214, and FIGS. 17A-18 correspond to an example of the method 70 applied to coupling two bonding surfaces 216.

Referring to FIGS. 5, 15A, and 17A, the method 70 at operation 72 provides two semiconductor structures 200 each including the bonding surface 214/216 formed according the methods 10, 30, and/or 50 described herein. For example, each bonding surface 214/216 includes the dielectric layer 204 and the conductive feature 206 disposed in the dielectric layer 204, where the sidewalls of the conductive feature 206 are separated from the sidewalls of the dielectric layer 204 by the spacers 209/212 and the barrier layer 205.

Subsequently, still referring to FIGS. 5, 15A, and 17A, the method 70 at operation 74 performs an activation process 82 during which a plasma is applied to the bonding surfaces 214/216 in preparation for the bonding process. In some implementations, the plasma includes an N₂ plasma, an O₂ plasma, the like, or combinations thereof.

Referring to FIGS. 5, 15B, and 17B, the method 70 at operation 76 performs a hydration or rinsing process 84 to further treat the bonding surfaces 214/216. In some implementations, the hydration process 84 is performed by applying a deionized water rinse. In some implementations, the hydration process 84 may form polar groups, such as hydroxyl groups —OH, at the respective bonding surfaces 214/216, thereby enhancing the bonding between portions (e.g., the dielectric layer 204) of the bonding surfaces 214/216. In some implementations, the method 70 may perform any other steps to treat the bonding surfaces 214/216 for in preparation for the bonding process.

Referring to FIGS. 5, 15C, and 17C, the method 70 at operation 78 couples together two bonding surfaces 214/216 of their respective semiconductor structures 200 to form a semiconductor structure 500, thereby defining a bonding interface 502/504. In some implementations, one of the semiconductor structures 200 may be first flipped or inverted (e.g., rotated 180°), such that the two bonding surfaces 214/216 are disposed opposing one another and bonded in a face-to-face configuration during an alignment process.

The bonding surfaces 214/216 may be coupled by any suitable process, such as by a hybrid bonding process. In this regard, the bonding process may be implemented by aligning conductive features or portions thereof disposed the opposing bonding surfaces 214/216 with one another, such that metal-to-metal coupling is formed across the bonding interface 502/504 between the conductive features 206 and dielectric-to-dielectric coupling is formed across the bonding interface 502/504 between the dielectric layers 204.

It should be noted that, although FIGS. 15C and 17C each depict two identical but opposing bonding surfaces, the present disclosure does not require such configuration. In one example, one of the bonding surfaces may include the bonding surface 214, and the other one of the bonding surfaces may include the bonding surface 216. In another example, one of the bonding surfaces may include either the bonding surface 214 or the bonding surface 216, and the other one of the bonding surfaces may include features and functions different from those of the bonding surface 214 and 216.

Referring to FIGS. 5, 15D, and 17D, the method 70 at operation 80 performs an annealing process 86 to fuse the bonding surfaces 214/216 across the bonding interface 502/504. In some implementations, the annealing process 86 is implemented by applying thermal energy to the semiconductor structure 500, thereby allowing the conductive features 206 of the opposing bonding surfaces 214/216 to expand across the bonding interface 502/504, and bond with one another. In some non-limiting examples, the annealing process 86 may be performed at a temperature ranging from about 200° C. to about 400° C. (e.g., at about 350° C.). Subsequently, the fusing of the respective conductive features 206 and the respective dielectric layers 204 results in the bonded semiconductor structure 500.

In some implementations, referring to FIGS. 16 and 18, as the sidewalls of the conductive features 206 physically contact the spacers 209/212 (e.g., the SAM 207), which lowers the surface energy of the underlying layer (e.g., barrier layer 205), the surface energy of the central portion of the conductive feature 206 is increased relative to the underlying layer. As the thermal energy is applied (e.g., at a temperature of at least about 200° C.), the central portion of the conductive feature 206 has less resistance to expansion than the edge portions in contact with the spacers 209/212, thereby causing the bulging effect that increases an area of contact between the opposing conductive features 206 across the bonding interface 502/504. As shown in FIGS. 16 and 18, the bulging of the top surface of the conductive feature 206 may be defined by the curve 220, which has a greater contact angle (e.g., the contact angle α as defined herein) than that of the curve 222 (e.g., the contact angle β as defined herein), an example profile of the top surface of the conductive feature 206 without the presence of the spacers 209/212.

In some implementations, portions of the bonding surfaces 214/216, e.g., the top surface of the conductive feature 206 and/or the top surface of the dielectric layer 204, may be texturized (e.g., nanotextured) to further improve the expansion characteristics of the conductive feature 206. In some examples, a dilute acid may be used to roughen the portions of the bonding surfaces 214/216, thereby increasing the contact angle of the top surface of the conductive feature 206.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“ Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor structure, comprising:
a semiconductor substrate;
a dielectric layer disposed over the semiconductor substrate;
a conductive feature embedded in the dielectric layer;
a barrier layer disposed between the conductive feature and the dielectric layer; and
a self-assembled monolayer (SAM) disposed over the barrier layer, at least a portion of the SAM directly contacting the conductive feature.

2. The semiconductor structure of claim 1, wherein the SAM is disposed between the conductive feature and the barrier layer such that an entirety of the SAM directly contacts the conductive feature.

3. The semiconductor structure of claim 2, wherein the SAM directly contacts a sidewall of the conductive feature and a sidewall of the barrier layer.

4. The semiconductor structure of claim 2, wherein a bottom surface of the conductive feature directly contacts the barrier layer.

5. The semiconductor structure of claim 1, wherein the SAM directly contacts a top portion of a sidewall of the barrier layer, and wherein the conductive feature directly contacts a bottom portion of the sidewall of the barrier layer below the top portion.

6. The semiconductor structure of claim 1, wherein an interface between a top portion of the conductive feature and a top portion of the barrier layer has an inwardly sloped profile.

7. The semiconductor structure of claim 1, wherein an interface between a top portion of the barrier layer and a top portion of the dielectric layer has an outwardly sloped profile.

8. A semiconductor structure, comprising:
a semiconductor substrate;
a dielectric layer disposed over the semiconductor substrate, the dielectric layer having a recess;
a conductive feature disposed in the recess; and
a barrier layer disposed between the dielectric layer and the conductive feature, wherein a top portion of a sidewall of the barrier layer has a sloped profile and a bottom portion of the sidewall of the barrier layer has a vertical profile.

9. The semiconductor structure of claim 8, wherein the sloped profile is an inwardly sloped profile.

10. The semiconductor structure of claim 8, wherein the sloped profile is an outwardly sloped profile.

11. The semiconductor structure of claim 8, further comprising a self-assembled monolayer (SAM) disposed between the barrier layer and the conductive feature.

12. The semiconductor structure of claim 8, further comprising a self-assembled monolayer (SAM), wherein the SAM directly contacts the top portion of the sidewall of the barrier layer, and wherein the conductive feature directly contacts a bottom portion of the sidewall of the barrier layer below the top portion.

13. A method, comprising:
providing a semiconductor substrate; and
forming a bonding surface over the semiconductor substrate, comprising:
forming a dielectric layer over the semiconductor substrate;
forming a recess in the dielectric layer;
forming a barrier layer in the recess;
forming a self-assembled monolayer (SAM) over the barrier layer; and
forming a conductive feature over the barrier layer, the conductive feature contacting at least a portion of the SAM.

14. The method of claim 13, wherein the SAM is formed to directly contact sidewalls and a bottom surface of the barrier layer, further comprising:
removing a portion of the SAM over the bottom surface of the barrier layer; and
subsequently forming the conductive feature over a remaining portion of the SAM.

15. The method of claim 14, wherein the removing of the portion of the SAM includes applying an anisotropic etching process using UV radiation with ozone.

16. The method of claim 14, further comprising recessing a top portion of the conductive feature to partially expose the SAM.

17. The method of claim 13, wherein the conductive feature is formed to directly contact sidewalls and a bottom surface of the barrier layer, further comprising:
removing a top portion of the conductive feature to partially expose the sidewalls of the barrier layer; and
subsequently forming the SAM over the recessed conductive feature and the partially exposed sidewalls of the barrier layer.

18. The method of claim 13, wherein the forming of the barrier layer includes performing a deposition process being tuned to form the barrier layer having an outwardly sloped sidewall adjacent to a top surface of the dielectric layer.

19. The method of claim 13, wherein the forming of the barrier layer includes performing a deposition process being tuned to form the barrier layer having an inwardly sloped sidewall adjacent to a top surface of the dielectric layer.

20. The method of claim 13, wherein the semiconductor substrate is a first semiconductor substrate, the bonding surface is a first bonding surface, and the conductive feature is a first conductive feature, further comprising:
providing a second semiconductor substrate having a second bonding surface formed thereover, the second bonding surface including a second conductive feature;
bonding the first semiconductor substrate to the second semiconductor substrate to form a bonding interface; and
annealing to fuse the first conductive feature with the second conductive feature across the bonding interface.
